(19) United States
(12) Patent Application Publication
(10) Pub. No.: US 2026/0305021 A1
(43) Pub. Date: Oct. 1, 2026

(54) LIGHT EMITTING DIODE AND MANUFACTURING METHOD THEREOF

(71) Applicant: Taiwan-Asia Semiconductor Corporation, Hsinchu City (TW)

(72) Inventors: Kun-Li Lin, Hsinchu City (TW); Chuan-Wei Chen, Hsinchu City (TW); Huang-Ming Chen, Hsinchu City (TW)

(21) Appl. No.: 19/317,692

(22) Filed: Sep. 3, 2025

(30) Foreign Application Priority Data
Apr. 1, 2025 (TW) 114112674

(51) Int. Cl. H10H 20/816; H10H 20/01; H10H 20/824

(52) U.S. Cl. CPC H10H 20/816; H10H 20/0133; H10H 20/824

(57) ABSTRACT

A light-emitting diode and a manufacturing method thereof are provided. The light-emitting diode includes a conductive substrate, a transparent conductive layer, and an epitaxial composite layer. The transparent conductive layer has a plurality of conductive plugs and is disposed on the conductive substrate. The epitaxial composite layer has a light-emitting layer and a first conductive type in-situ doped epitaxial bottom layer, disposed on the transparent conductive layer. The first conductive type in-situ doped epitaxial bottom layer has a second conductive type local diffusion zone disposed therein and in contact with the conductive plugs, such that the current flowing through the light-emitting layer substantially flows directly through the second conductive type local diffusion zone into the conductive plugs.

### CROSS-REFERENCES TO RELATED APPLICATIONS

This application claims the benefit of priority to Taiwanese Patent Application No. 114112674 filed on Apr. 1, 2025, which is hereby incorporated by reference in its entirety.

### BACKGROUND OF THE INVENTION

### Field of the Invention

This invention relates to a light-emitting diode and a manufacturing method thereof, and in particular to a light-emitting diode with high brightness and a manufacturing method thereof.

### Descriptions of the Related Art

A light-emitting diode (LED) offers advantages such as high brightness, small size, low power consumption, and long lifespan, making it widely used in optoelectronic products such as lighting and displays. Referring to FIG. 1, a common design for high-brightness LEDs is illustrated. The light-emitting diode shown in FIG. 1 comprises an epitaxial composite layer 20 disposed on a substrate 10, which includes a P-type epitaxial layer 21, a light-emitting layer 22, and an N-type epitaxial layer 23. A transparent conductive layer 30 is interposed between the substrate and the epitaxial composite layer 20, with the transparent conductive layer 30 containing a plurality of conductive plugs 32. These conductive plugs 32 serve both as ohmic contacts between the epitaxial layer and a metal reflective layer and for current spreading.

In the actual operation of this conventional light-emitting diode, an external current injected from the upper electrode 40 partially flows along path A, as shown in FIG. 1, through the light-emitting layer 22 and the P-type epitaxial layer 21, and then into the conductive plugs 32. However, a portion of the current may flow under the upper electrode 40 due to the lower resistance across the PN junction. As shown, along path B, the current flows through the light-emitting layer 22 and the P-type epitaxial layer 21 beneath the upper electrode 40, and then into the conductive plugs 32. When the current along path B flows through the light-emitting layer 22, the light generated may be partially blocked by the upper electrode 40 due to their vertical overlap, reducing the efficiency of light emission and causing a pad shadowing issue.

On the other hand, after the mesa etching process, the sidewall regions of the mesa epitaxial layer in the light-emitting diode may develop lattice defects due to etching, making the peripheral sidewalls susceptible to electrical overstress (EOS) or electrostatic discharge (ESD) damage, leading to leakage current and device failure. To address these issues, there is an urgent need in the industry for an innovative light-emitting diode and manufacturing method to enhance brightness and improve ESD resistance.

### SUMMARY OF THE INVENTION

The main objective of this invention is to provide a high-brightness light-emitting diode with enhanced ESD resistance and a manufacturing method thereof. The light-emitting diode of this invention employs localized impurity doping and diffusion processes to precisely control the current path distribution, ensuring that the light-emitting region excited by the current path avoids being shadowed by the electrode pad in the vertical direction, thereby achieving enhanced brightness. Additionally, the light-emitting diode of this invention prevents current from being conducted in the peripheral regions of the mesa epitaxial layer, thereby improving the device's ESD resistance.

To achieve the above objective, this invention provides a light-emitting diode comprising a conductive substrate, a transparent conductive layer, and an epitaxial composite layer. The transparent conductive layer includes a plurality of conductive plugs and is disposed on the conductive substrate. The epitaxial composite layer includes a light-emitting layer and a first conductive type in-situ doped epitaxial bottom layer, disposed on the transparent conductive layer. The first conductive type in-situ doped epitaxial bottom layer includes a second conductive type local diffusion zone disposed therein and in contact with the conductive plugs, such that the current flowing through the light-emitting layer substantially flows directly through the second conductive type local diffusion zone into the conductive plugs.

In one embodiment of the light-emitting diode of this invention, the first conductive type in-situ doped epitaxial bottom layer is an N-type indium phosphide (InP) epitaxial layer, and the second conductive type local diffusion zone is a P-type indium phosphide (InP) local diffusion zone.

In one embodiment of the light-emitting diode of this invention, the second conductive type local diffusion zone is spaced apart from the sidewall of the epitaxial composite layer by a spacing, such that the second conductive type local diffusion zone does not contact the sidewall of the epitaxial composite layer.

In one embodiment of the light-emitting diode of this invention, the light-emitting diode further includes an upper electrode disposed on the epitaxial composite layer, wherein the upper electrode does not overlap with the second conductive type local diffusion zone in the vertical direction, such that the current injected from the upper electrode flows through the light-emitting layer and substantially directly through the second conductive type local diffusion zone into the conductive plugs.

In one embodiment of the light-emitting diode of this invention, the light-emitting layer is an intrinsic indium gallium arsenide (InGaAs) epitaxial layer.

In one embodiment of the light-emitting diode of this invention, the light-emitting layer is a second conductive type lightly doped indium gallium arsenide (InGaAs) epitaxial layer.

In one embodiment of the light-emitting diode of this invention, each of the conductive plugs is a second conductive type ohmic contact plug.

In one embodiment of the light-emitting diode of this invention, the second conductive type ohmic contact plug is a P-type indium gallium arsenide phosphide (InGaAsP) conductive plug.

To achieve the above objective, this invention provides a light-emitting diode comprising a conductive substrate, an epitaxial composite layer, and an upper electrode. The epitaxial composite layer includes a light-emitting layer and a first conductive type in-situ doped epitaxial bottom layer. The first conductive type in-situ doped epitaxial bottom layer includes a second conductive type local diffusion zone disposed therein and not overlapping with the upper electrode in the vertical direction, such that the current injected from the upper electrode flows through the light-emitting layer and substantially directly through the second conductive type local diffusion zone into the conductive substrate.

In another embodiment of the light-emitting diode of this invention, the first conductive type in-situ doped epitaxial bottom layer is an N-type indium phosphide (InP) epitaxial layer, and the second conductive type local diffusion zone is a P-type indium phosphide (InP) local diffusion zone.

In another embodiment of the light-emitting diode of this invention, the second conductive type local diffusion zone is spaced apart from the sidewall of the epitaxial composite layer by a spacing, such that the second conductive type local diffusion zone does not contact the sidewall of the epitaxial composite layer.

In another embodiment of the light-emitting diode of this invention, the light-emitting diode further includes a transparent conductive layer having a plurality of conductive plugs disposed between the conductive substrate and the epitaxial composite layer, forming ohmic contact with the second conductive type local diffusion zone, such that the current injected from the upper electrode flows through the light-emitting layer and substantially directly through the second conductive type local diffusion zone into the conductive plugs.

In another embodiment of the light-emitting diode of this invention, each of the conductive plugs is a P-type indium gallium arsenide phosphide (InGaAsP) conductive plug.

In another embodiment of the light-emitting diode of this invention, the light-emitting layer is an intrinsic indium gallium arsenide (InGaAs) epitaxial layer.

In another embodiment of the light-emitting diode of this invention, the light-emitting layer is a second conductive type lightly doped indium gallium arsenide (InGaAs) epitaxial layer.

To achieve the above objective, this invention provides a manufacturing method for a light-emitting diode, comprising the following steps. First, provide an epitaxial composite layer disposed on an epitaxial growth substrate, wherein the epitaxial composite layer including a light-emitting layer and a first conductive type in-situ doped epitaxial bottom layer. Second, provide a plurality of conductive plugs disposed on the epitaxial composite layer. Third, provide a second conductive type local diffusion zone disposed in the first conductive type in-situ doped epitaxial bottom layer and form ohmic contact with the conductive plugs. And finally, provide a conductive substrate bonded to the epitaxial growth substrate via wafer bonding and remove the epitaxial growth substrate, wherein the current flowing through the light-emitting layer substantially flows directly through the second conductive type local diffusion zone into the conductive plugs and into the conductive substrate.

In one embodiment of the manufacturing method for the light-emitting diode of this invention, the step of providing a second conductive type local diffusion zone is to provide a patterned mask layer disposed on the epitaxial composite layer and expose the conductive plugs to perform an ion doping and diffusion process.

In one embodiment of the manufacturing method for the light-emitting diode of this invention, the step of performing an ion doping and diffusion process is to space the second conductive type local diffusion zone apart from the sidewall of the epitaxial composite layer by a spacing, such that the second conductive type local diffusion zone does not contact the sidewall of the epitaxial composite layer.

In one embodiment of the manufacturing method for the light-emitting diode of this invention, further includes a step of providing an upper electrode disposed on the epitaxial composite layer, wherein the upper electrode does not overlap with the second conductive type local diffusion zone in the vertical direction, such that the current injected from the upper electrode flows through the light-emitting layer and substantially directly through the second conductive type local diffusion zone into the conductive plugs and into the conductive substrate.

In one embodiment of the manufacturing method for the light-emitting diode of this invention, the step of providing the epitaxial composite layer includes a step of providing a second conductive type lightly doped indium gallium arsenide (InGaAs) epitaxial layer as the light-emitting layer.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 is a schematic diagram of a conventional light-emitting diode;

FIG. 2 to FIG. 9 are schematic diagrams illustrating the manufacturing of a light-emitting diode in one embodiment of this invention;

FIG. 10 is a schematic diagram illustrating the current path of a light-emitting diode in one embodiment of this invention;

FIG. 11 is a schematic diagram illustrating the energy band of the epitaxial layers of a light-emitting diode in one embodiment of this invention;

FIG. 12 is a top-view schematic diagram of a light-emitting diode in one embodiment of this invention; and

FIG. 13 is a schematic diagram illustrating the process steps of a light-emitting diode in this invention.

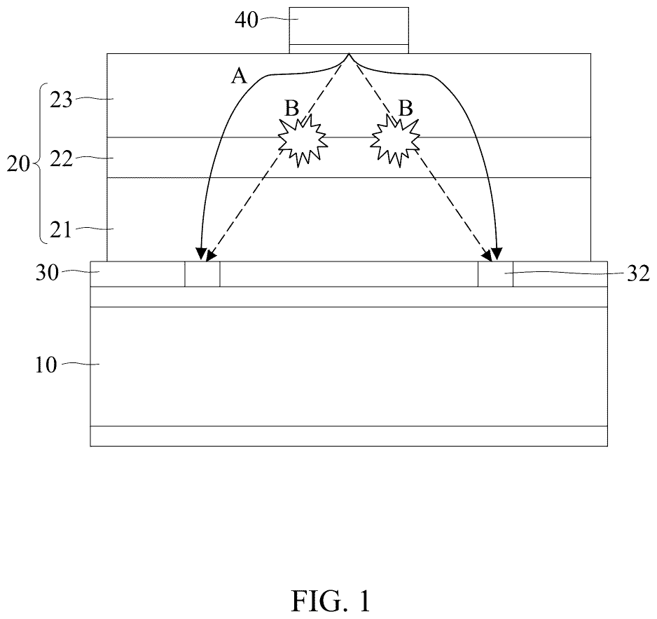

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

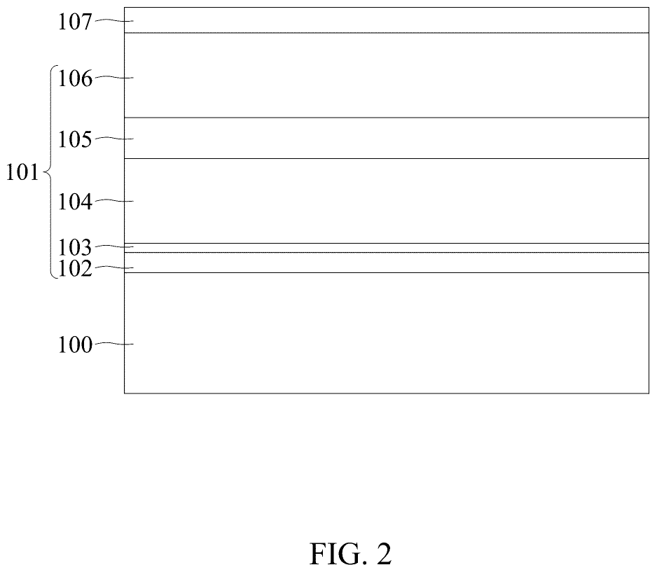

This invention discloses a light-emitting diode and a manufacturing method thereof. Specifically, the light-emitting diode of this invention employs localized diffusion in the epitaxial layer to achieve uniform current distribution, thereby improving the light extraction efficiency of the light-emitting diode, as detailed below. Referring to FIG. 2, a short-wave infrared light-emitting diode in one embodiment of this invention uses indium phosphide (InP) as an epitaxial growth substrate 100, though it is not limited thereto. Subsequently, an epitaxial composite layer 101 is grown on the epitaxial growth substrate 100 using metal-organic chemical vapor deposition (MOCVD) or molecular beam epitaxy (MBE) techniques. The epitaxial composite layer 101 includes an intrinsic epitaxial layer 102, such as an indium phosphide (InP) layer, to ensure high-quality epitaxial growth. Next, a buffer epitaxial layer 103, such as an indium gallium arsenide (InGaAs) epitaxial layer, is grown on the intrinsic epitaxial layer 102 to facilitate lattice matching for subsequent growth of the light-emitting layer and to form good ohmic contact with electrodes.

Next, the epitaxial composite layer 101 further includes, sequentially on the buffer epitaxial layer 103, a first conductive type in-situ doped epitaxial layer 104, a light-emitting layer 105, and a first conductive type in-situ doped epitaxial layer 106. The light-emitting layer 105 is a multiple quantum well (MQW) structure, specifically an intrinsic indium gallium arsenide (InGaAs) epitaxial layer, sandwiched between two first conductive type in-situ doped epitaxial layers 104 and 106. In a preferred embodiment, the light-emitting layer 105 may be a P-type lightly doped indium gallium arsenide (InGaAs) epitaxial layer. In this embodiment, the emission wavelength band of the light-emitting layer 105 may range from 1100 to 1700 nanometers (nm). It should be noted that the materials described for the light-emitting layer are merely exemplary, and the present invention is not limited thereto. In practical applications, the material and composition of the epitaxial layer can be adjusted based on the emission wavelength, such as aluminum gallium indium phosphide (AlGaInP), indium gallium phosphide (InGaP), or aluminum gallium arsenide (AlGaAs).

On the other hand, the first conductive type in-situ doped epitaxial layer 104 and the first conductive type in-situ doped epitaxial layer 106 are specifically N-type lightly doped indium phosphide (InP) epitaxial layers, with doping elements including, but not limited to, sulfur(S) or silicon (Si), and a doping concentration of approximately 10¹⁶ to 10¹⁷ cm⁻³. Finally, during the epitaxial process, an intrinsic epitaxial layer 107, such as, but not limited to, an intrinsic indium gallium arsenide phosphide (InGaAsP) epitaxial layer, is grown on the first conductive type in-situ doped epitaxial layer 106 for use as conductive plugs in a ohmic contact layer subsequently formed.

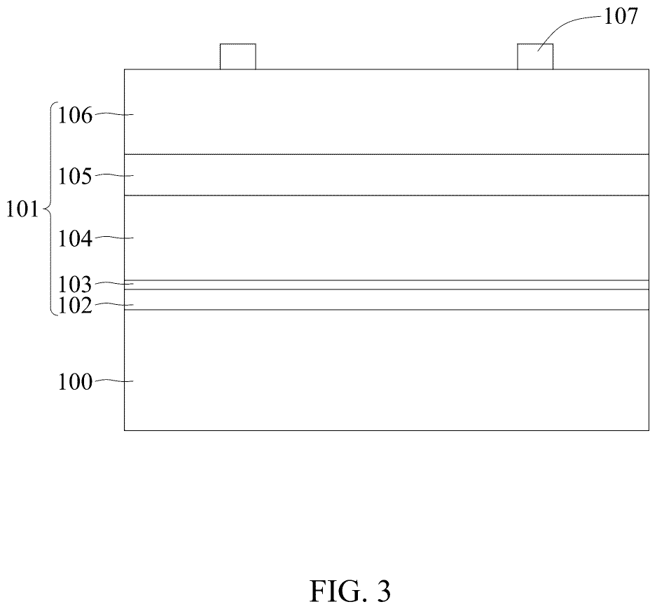

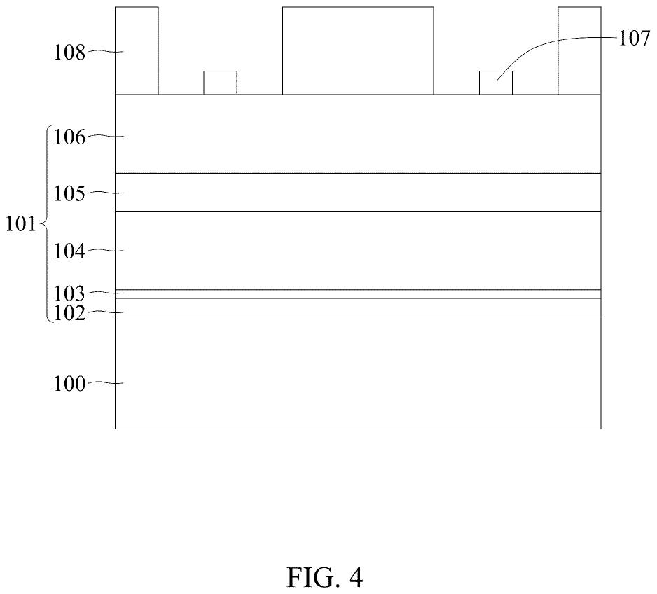

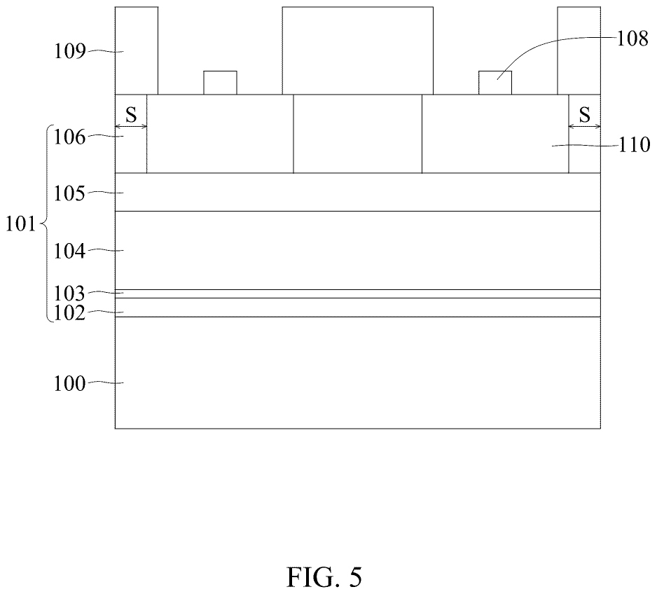

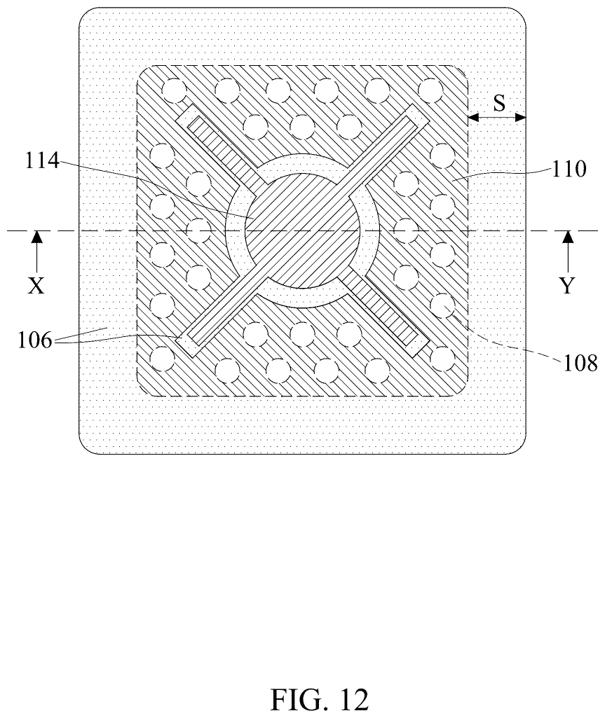

Referring to FIG. 3, a patterning process is performed based on the need for uniform current distribution in the light-emitting diode and in coordination with the pattern design of electrode pads subsequently formed, for removing portions of the intrinsic epitaxial layer 107 to form a plurality of patterned intrinsic epitaxial layers 107 on the first conductive type in-situ doped epitaxial layer 106. Next, referring to FIG. 4 and FIG. 5 together, a localized ion doping and diffusion process is illustrated. Specifically, a patterned mask layer 109 is formed on the first conductive type in-situ doped epitaxial layer 106, exposing the plurality of patterned intrinsic epitaxial layers 107 on the surface of the first conductive type in-situ doped epitaxial layer 106 and portions of the exposed surface of the first conductive type in-situ doped epitaxial layer 106 around the patterned intrinsic epitaxial layers 107. Subsequently, an ion doping and diffusion process is performed to form a second conductive type local diffusion zone 110 in the exposed regions of the first conductive type in-situ doped epitaxial layer 106, as shown in FIG. 5. In particular, referring to FIG. 12, which shows a top-view schematic diagram of the light-emitting diode in one embodiment of this invention, FIG. 5 represents a cross-sectional view along a line XY in FIG. 12. FIG. 12 clearly shows that the second conductive type local diffusion zone 110 is a region in the first conductive type in-situ doped epitaxial layer 106 subjected to the aforementioned ion doping and diffusion, while the regions outside the second conductive type local diffusion zone 110 remain undoped diffusion regions of the first conductive type in-situ doped epitaxial layer 106.

Specifically, an ion doping and diffusion process with doping elements such as zinc (Zn) or carbon (C) and a doping concentration of approximately 10¹⁶ to 10¹⁷ cm⁻³ is performed to form localized low-resistance P-type contact diffusion zones. It should be emphasized that the pattern contour of the second conductive type local diffusion zone 110 is designed based on the pattern of the upper electrode 114 (as shown in FIG. 12) to be formed in subsequent processes, ensuring that these two parts do not overlap in the vertical direction, thereby achieving uniform current distribution and avoiding shadowing by the upper electrode to enhance light extraction efficiency, as detailed below. Additionally, the second conductive type local diffusion zone 110 has another technical feature of being spaced apart from the sidewall of the epitaxial composite layer 101 by a spacing S, such that the second conductive type local diffusion zone 110 does not contact the sidewall of the epitaxial composite layer 101, thereby enhancing the ESD resistance of the light-emitting diode, as detailed below.

On the other hand, in a preferred embodiment of this invention, the plurality of patterned intrinsic epitaxial layers 107, affected by the ion doping and diffusion process, are simultaneously converted into a plurality of patterned second conductive type epitaxial layers. As mentioned earlier, when the intrinsic epitaxial layer 107 is an intrinsic indium gallium arsenide phosphide (InGaAsP) epitaxial layer, after the ion doping and diffusion process, the plurality of patterned second conductive type epitaxial layers become a plurality of patterned P-type indium gallium arsenide phosphide (InGaAsP) epitaxial layers, specifically used as a plurality of conductive plugs 108 in the final light-emitting diode structure, forming good ohmic contact with the metal reflective layer formed in subsequent processes (i.e., the conductive plugs 108 are second conductive type ohmic contact plugs, specifically P-type indium gallium arsenide phosphide (InGaAsP) conductive plugs), as shown in FIG. 5 and FIG. 12.

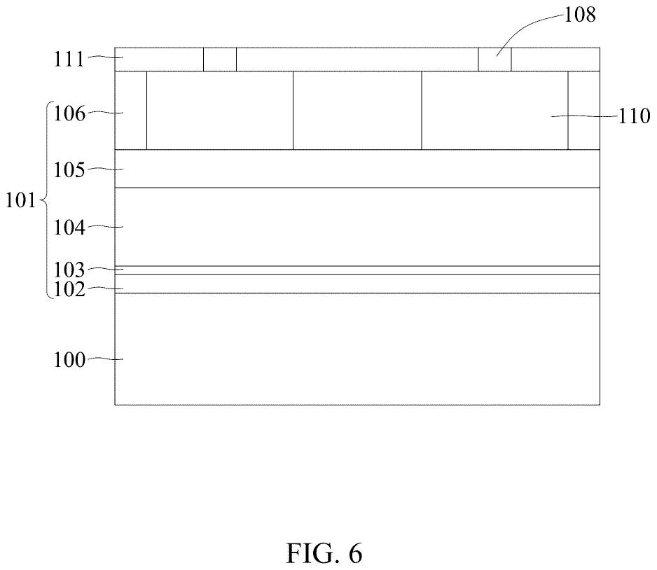

Referring to FIG. 6, after removing the patterned mask layer 109, a transparent conductive layer 111 is formed by evaporation to cover the plurality of conductive plugs 108, the undoped diffusion regions of the first conductive type in-situ doped epitaxial layer 106, and the second conductive type local diffusion zone 110, and is electrically connected to the conductive plugs 108. The material of the transparent conductive layer 111 is made by one of indium tin oxide (ITO), aluminum zinc oxide (AZO), indium zinc oxide (IZO), nickel oxide, indium tin oxide, cadmium tin oxide, antimony tin oxide, or combinations thereof.

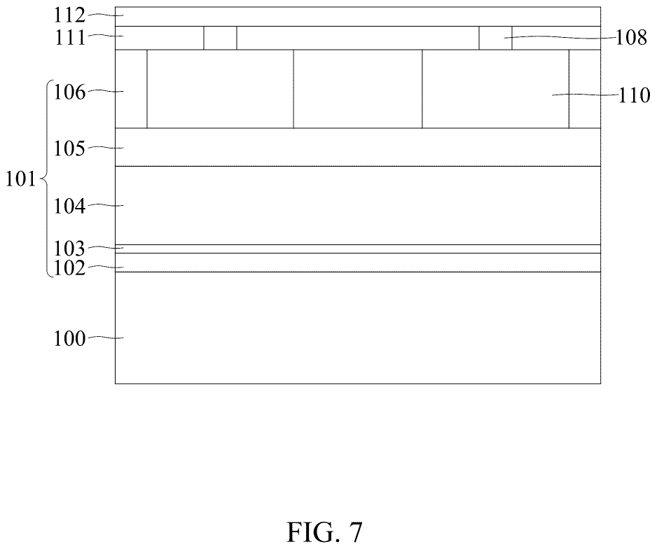

Referring to FIG. 7, a reflective mirror layer 112 is deposited on the transparent conductive layer 111. This reflective mirror layer 112 is specifically a metal stack, deposited gradually by metal evaporation or sputtering, forming good ohmic contact with the interfaces of the conductive plugs 108. The material of the reflective mirror layer 112 is selected from the group consisting of silver (Ag), titanium (Ti), platinum (Pt), gold (Au), and combinations thereof, forming a mirror system for the light-emitting diode. This reflective mirror layer has high reflectivity, effectively reflecting light within the light-emitting diode structure to enhance emission intensity and reduce absorption loss within the structure.

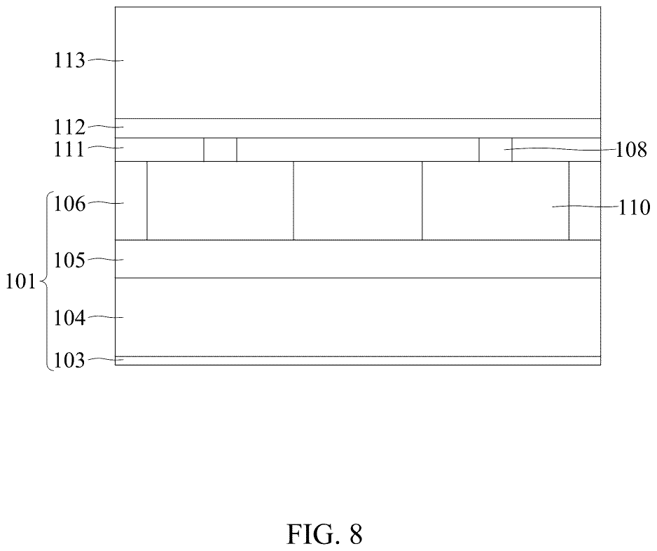

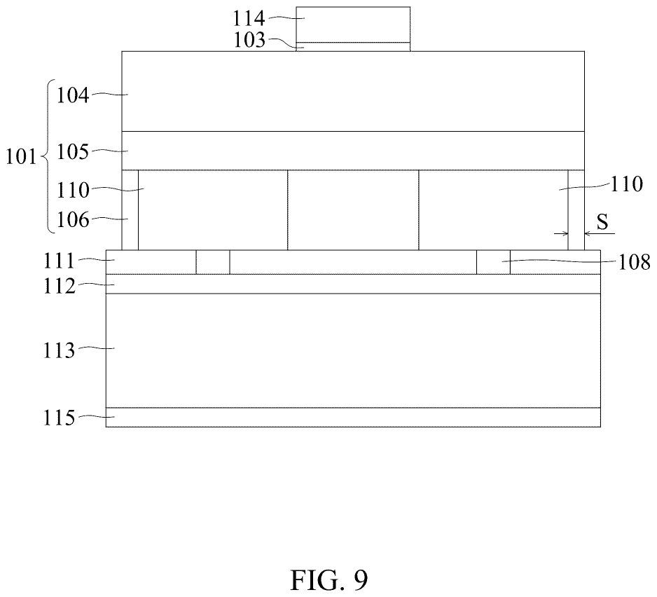

Referring to FIG. 8, wafer bonding technology is used to bond the epitaxial growth substrate 100 to a conductive substrate 113. The conductive substrate 113 may be, but is not limited to, a silicon substrate or a sapphire substrate. Specifically, after bonding one side of the reflective mirror layer 112 on the epitaxial growth substrate 100 to the conductive substrate 113, a wafer removal process is performed to remove the epitaxial growth substrate 100 and the intrinsic epitaxial layer 102 from one side of the conductive substrate 113, exposing the buffer epitaxial layer 103. Subsequently, the wafer is flipped so the conductive substrate 113 acts as the bottom support structure of the light-emitting diode chip, the first conductive type in-situ doped epitaxial layer 104 becomes a first conductive type in-situ doped epitaxial upper layer, and the first conductive type in-situ doped epitaxial layer 106 becomes a first conductive type in-situ doped epitaxial bottom layer for facilitating subsequent processes such as wafer dicing. As shown in FIG. 9, a mesa etching process is performed on the epitaxial composite layer 101, etching portions of the first conductive type in-situ doped epitaxial upper layer, the light-emitting layer 105, and the first conductive type in-situ doped epitaxial bottom layer. Subsequently, a metal layer is formed on the buffer epitaxial layer 103, and a patterning etching process is performed on the metal layer and the buffer epitaxial layer 103 to form an upper electrode 114. Additionally, a metal evaporation process is performed on the back side of the conductive substrate 113 to form a lower electrode 115, completing the final structure of the light-emitting diode of this invention.

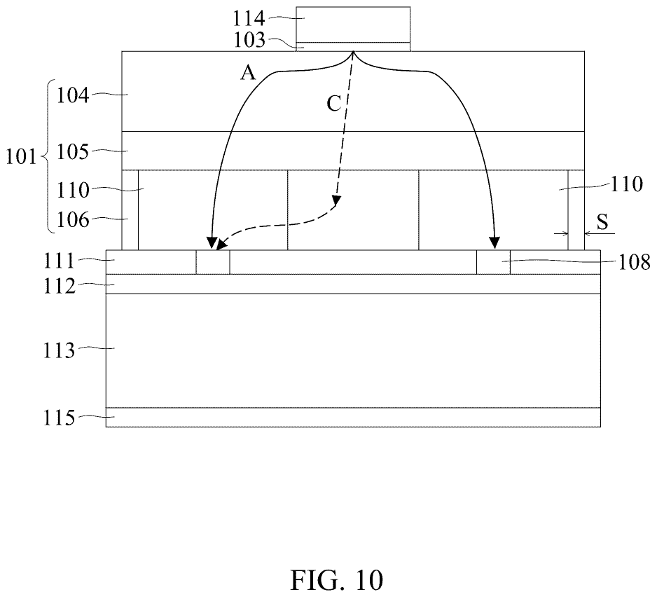

Referring to FIG. 10, a schematic diagram of a light-emitting diode in one embodiment of this invention is shown. The first conductive type in-situ doped epitaxial layer 106 (i.e., the first conductive type in-situ doped epitaxial bottom layer) in the epitaxial composite layer 101 is disposed on the transparent conductive layer 111. Specifically, the first conductive type in-situ doped epitaxial bottom layer includes a second conductive type local diffusion zone 110 disposed on each conductive plug. When an external current is injected into the upper electrode 114, the current flows along path A, as shown in FIG. 10, through the first conductive type in-situ doped epitaxial layer 104, the light-emitting layer 105, and substantially directly through the second conductive type local diffusion zone 110 into the conductive plugs 108, then through the reflective mirror layer 112 and the conductive substrate 113 to the lower electrode 115. In contrast, the external current does not flow along path C, as shown in FIG. 10, i.e., the current does not flow into the undoped diffusion regions of the first conductive type in-situ doped epitaxial layer 106 (i.e., the first conductive type in-situ doped epitaxial bottom layer).

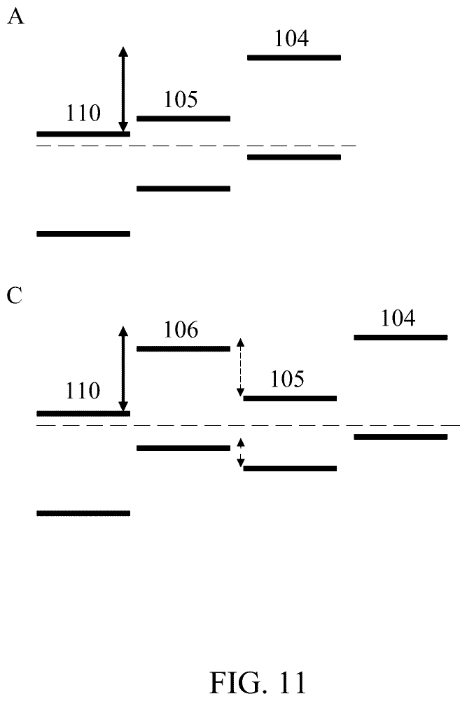

The following explains, with reference to the energy band diagram in FIG. 11, why the external current injected from the upper electrode follows path A instead of path C. Specifically, the upper part of FIG. 11 shows the built-in potential diagram of the epitaxial layers along path A. Clearly, when an external current is applied and an external voltage overcomes the built-in potential of the PN diode, i.e., overcomes the energy band between the second conductive type local diffusion zone 110 (i.e., P-type doped InP layer) and the light-emitting layer 105 (i.e., P-type lightly doped InGaAs layer), and between the light-emitting layer 105 (i.e., P-type lightly doped InGaAs layer) and the first conductive type in-situ doped epitaxial layer 104 (i.e., N-type doped InP layer), conduction occurs. Conversely, if the external current follows path C, the energy band diagram of the epitaxial layers along this path is shown in the lower part of FIG. 11, i.e., the P-N-P-N junction structure includes a reverse built-in potential between the first conductive type in-situ doped epitaxial layer 106 (i.e., undoped diffusion region) and the light-emitting layer 105, preventing conduction and making it impossible for the current to flow through path C.

Comparing the two paths, when the current follows path A and flows through the light-emitting layer 105, the position does not overlap with the upper electrode 114 in the vertical direction. Therefore, the light generated at this point is not shadowed by the upper electrode 114, allowing the light to emit outward smoothly without being obstructed. Conversely, if the current follows path C and flows through the light-emitting layer 105, the light generated is shadowed by the upper electrode 114 due to their vertical overlap, reducing light extraction efficiency. Thus, through the strategic arrangement of the second conductive type local diffusion zone 110, which does not overlap with the upper electrode in the vertical direction, and the energy band structure caused by the epitaxial layer configuration, this invention ensures uniform current distribution within the epitaxial composite layer of the light-emitting diode, significantly reducing shadowing by the electrode pad and greatly enhancing the emission efficiency of the light-emitting diode.

On the other hand, referring to FIG. 10 and FIG. 12 together, it is clearly shown that the undoped diffusion region in the first conductive type in-situ doped epitaxial layer 106 includes a peripheral region spaced apart from the sidewall by a spacing S, such that the second conductive type local diffusion zone 110 does not contact the sidewall of the epitaxial composite layer 101. According to the above embodiment, this spacing S region is an N-type lightly doped indium phosphide (InP) epitaxial layer. Similarly, in terms of the energy band of the epitaxial layers, if an external current flows from the first conductive type in-situ doped epitaxial layer 104, through the light-emitting layer 105, the peripheral sidewall region of the first conductive type in-situ doped epitaxial layer 106, the second conductive type local diffusion zone 110, and into the conductive plugs 108, this path would encounter the same P-N-P-N junction energy band structure. The reverse built-in potential between the undoped diffusion region in the peripheral area of the first conductive type in-situ doped epitaxial layer 106 and the light-emitting layer 105 similarly prevents current from flowing into this sidewall region, making the peripheral region non-conductive. This avoids the issue of leakage current in the peripheral region of the mesa epitaxial layer due to ESD or EOS surge current attacks, thereby enhancing the ESD resistance of the light-emitting diode.

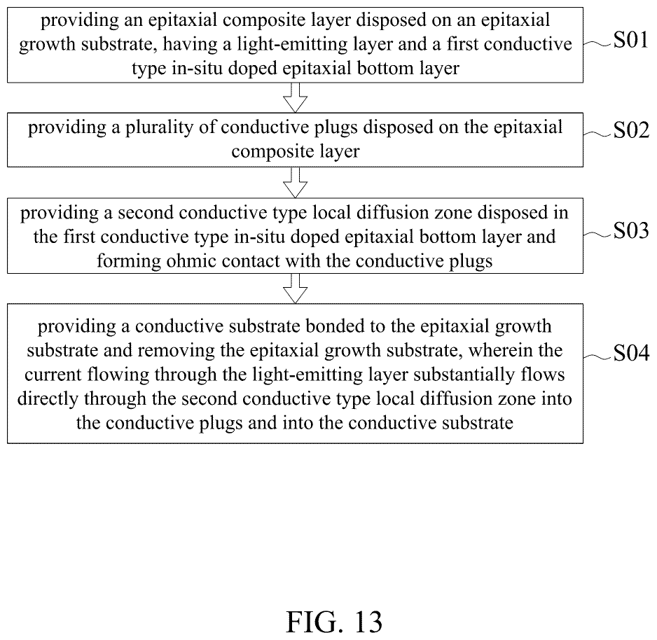

Referring to FIG. 13, a schematic diagram of the process flow for manufacturing the light-emitting diode of this invention is shown. First, in step S01, an epitaxial composite layer is provided on an epitaxial growth substrate, the epitaxial composite layer including a light-emitting layer and a first conductive type in-situ doped epitaxial bottom layer. In step S02, a plurality of conductive plugs are provided on the epitaxial composite layer. Next, in step S03, a second conductive type local diffusion zone is provided in the first conductive type in-situ doped epitaxial bottom layer, forming ohmic contact with the conductive plugs. In step S04, a conductive substrate is provided, bonded to the epitaxial growth substrate via wafer bonding, and the epitaxial growth substrate is removed, wherein the current flowing through the light-emitting layer substantially flows directly through the second conductive type local diffusion zone into the conductive plugs and into the conductive substrate. The descriptions of related components in the process steps can refer to the above content and will not be repeated here.

In summary, distinctly different from conventional epitaxial structures formed solely by in-situ doping, the light-emitting diode of this invention employs localized impurity doping and diffusion processes to control the current path distribution in the light-emitting diode for avoiding shadowing by the electrode pad and achieving enhanced brightness and ESD resistance. In a preferred embodiment, the light-emitting diode of this invention further optimizes the arrangement between the localized impurity diffusion zone and the conductive plugs to achieve more uniform current distribution, further enhancing brightness.

The above embodiments are provided to illustrate the implementations of the present invention and to explain its technical features, and are not intended to limit the scope of the present invention. Any modifications or equivalent arrangements that can be easily accomplished by those skilled in the art fall within the scope of the present invention, and the scope of the present invention should be defined by the claims.

What is claimed is:

1. A light-emitting diode, comprising:
a conductive substrate;
a transparent conductive layer having a plurality of conductive plugs, disposed on the conductive substrate; and
an epitaxial composite layer having a light-emitting layer and a first conductive type in-situ doped epitaxial bottom layer, disposed on the transparent conductive layer,
wherein the first conductive type in-situ doped epitaxial bottom layer includes a second conductive type local diffusion zone disposed therein and in contact with the conductive plugs, such that the current flowing through the light-emitting layer substantially flows directly through the second conductive type local diffusion zone into the conductive plugs.

2. The light-emitting diode of claim 1, wherein the first conductive type in-situ doped epitaxial bottom layer is an N-type indium phosphide (InP) epitaxial layer, and the second conductive type local diffusion zone is a P-type indium phosphide (InP) local diffusion zone.

3. The light-emitting diode of claim 1, wherein the second conductive type local diffusion zone is spaced apart from the sidewall of the epitaxial composite layer by a spacing, such that the second conductive type local diffusion zone does not contact the sidewall of the epitaxial composite layer.

4. The light-emitting diode of claim 1, further comprising an upper electrode disposed on the epitaxial composite layer, wherein the upper electrode does not overlap with the second conductive type local diffusion zone in the vertical direction, such that the current injected from the upper electrode flows through the light-emitting layer and substantially directly through the second conductive type local diffusion zone into the conductive plugs.

5. The light-emitting diode of claim 1, wherein the light-emitting layer is an intrinsic indium gallium arsenide (InGaAs) epitaxial layer.

6. The light-emitting diode of claim 1, wherein the light-emitting layer is a second conductive type lightly doped indium gallium arsenide (InGaAs) epitaxial layer.

7. The light-emitting diode of claim 1, wherein each of the conductive plugs is a second conductive type ohmic contact plug.

8. The light-emitting diode of claim 7, wherein the second conductive type ohmic contact plug is a P-type indium gallium arsenide phosphide (InGaAsP) conductive plug.

9. A light-emitting diode, comprising:
a conductive substrate;
an epitaxial composite layer disposed on the conductive substrate, having a light-emitting layer and a first conductive type in-situ doped epitaxial bottom layer; and
an upper electrode disposed on the epitaxial composite layer,
wherein the first conductive type in-situ doped epitaxial bottom layer includes a second conductive type local diffusion zone disposed therein and not overlapping with the upper electrode in the vertical direction, such that the current injected from the upper electrode flows through the light-emitting layer and substantially directly through the second conductive type local diffusion zone into the conductive substrate.

10. The light-emitting diode of claim 9, wherein the first conductive type in-situ doped epitaxial bottom layer is an N-type indium phosphide (InP) epitaxial layer, and the second conductive type local diffusion zone is a P-type indium phosphide (InP) local diffusion zone.

11. The light-emitting diode of claim 9, wherein the second conductive type local diffusion zone is spaced apart from the sidewall of the epitaxial composite layer by a spacing, such that the second conductive type local diffusion zone does not contact the sidewall of the epitaxial composite layer.

12. The light-emitting diode of claim 9, further comprising a transparent conductive layer having a plurality of conductive plugs disposed between the conductive substrate and the epitaxial composite layer, forming ohmic contact with the second conductive type local diffusion zone, such that the current injected from the upper electrode flows through the light-emitting layer and substantially directly through the second conductive type local diffusion zone into the conductive plugs.

13. The light-emitting diode of claim 12, wherein each of the conductive plugs is a P-type indium gallium arsenide phosphide (InGaAsP) conductive plug.

14. The light-emitting diode of claim 9, wherein the light-emitting layer is an intrinsic indium gallium arsenide (InGaAs) epitaxial layer.

15. The light-emitting diode of claim 9, wherein the light-emitting layer is a second conductive type lightly doped indium gallium arsenide (InGaAs) epitaxial layer.

16. A manufacturing method for a light-emitting diode, comprising:
providing an epitaxial composite layer disposed on an epitaxial growth substrate, having a light-emitting layer and a first conductive type in-situ doped epitaxial bottom layer;
providing a plurality of conductive plugs disposed on the epitaxial composite layer;
providing a second conductive type local diffusion zone disposed in the first conductive type in-situ doped epitaxial bottom layer and forming ohmic contact with the conductive plugs; and
providing a conductive substrate bonded to the epitaxial growth substrate and removing the epitaxial growth substrate,
wherein the current flowing through the light-emitting layer substantially flows directly through the second conductive type local diffusion zone into the conductive plugs and into the conductive substrate.

17. The manufacturing method for a light-emitting diode of claim 16, wherein the step of providing a second conductive type local diffusion zone is to provide a patterned mask layer disposed on the epitaxial composite layer and exposing the conductive plugs to perform an ion doping and diffusion process.

18. The manufacturing method for a light-emitting diode of claim 17, wherein the step of performing an ion doping and diffusion process ensures that the second conductive type local diffusion zone is spaced apart from the sidewall of the epitaxial composite layer by a spacing, such that the second conductive type local diffusion zone does not contact the sidewall of the epitaxial composite layer.

19. The manufacturing method for a light-emitting diode of claim 16, further comprising providing an upper electrode disposed on the epitaxial composite layer, wherein the upper electrode does not overlap with the second conductive type local diffusion zone in the vertical direction, such that the current injected from the upper electrode flows through the light-emitting layer and substantially directly through the second conductive type local diffusion zone into the conductive plugs and into the conductive substrate.

20. The manufacturing method for a light-emitting diode of claim 16, wherein the step of providing the epitaxial composite layer includes a step of providing a second conductive type lightly doped indium gallium arsenide (InGaAs) epitaxial layer as the light-emitting layer.
